(19) United States
(12) Patent Application Publication
(10) Pub. No.: US 2015/0200382 A1
(43) Pub. Date: Jul. 16, 2015

(54) ORGANIC LIGHT-EMITTING DIODE AND MANUFACTURING METHOD THEREOF

(71) Applicant: ELECTRONICS AND TELECOMMUNICATIONS RESEARCH INSTITUTE, Daejeon (KR)

(72) Inventors: Jaehyun MOON, Daejeon (KR); Seung Koo PARK, Daejeon (KR); Doo-Hee CHO, Daejeon (KR); Jonghee LEE, Daejeon (KR); Jin Woo HUH, Daejeon (KR); Jin Wook SHIN, Daejeon (KR); Jun-Han HAN, Daejeon (KR); Joo Hyun HWANG, Seoul (KR); Chul Woong JOO, Seoul (KR); Nam Sung CHO, Daejeon (KR); Jong Tae LIM, Seoul (KR); Byoung Gon YU, Yeongdong-gun (KR); Jeong Ik LEE, Daejeon (KR)

(73) Assignee: ELECTRONICS AND TELECOMMUNICATIONS RESEARCH INSTITUTE, Daejeon (KR)

(21) Appl. No.: 14/451,702

(22) Filed: Aug. 5, 2014

(30) Foreign Application Priority Data
Jan. 16, 2014 (KR) 10-2014-0005438

(51) Int. Cl. H01L 51/52; H01L 51/00; H01L 51/56

(52) U.S. Cl. CPC H01L 51/5271; H01L 51/56; H01L 51/0003; H01L 2251/5315; H01L 2251/558

(57) ABSTRACT

Provided is an organic light-emitting diode (OLED) including: a substrate; a wide viewing-angle homogenization layer on the substrate; a first electrode layer on the wide viewing-angle homogenization layer; a hole transport layer on the first electrode layer; an organic emission layer disposed on the hole transport layer to emit a light; an electron transport layer on the organic emission layer; and a second electrode layer on the electron transport layer.

### CROSS-REFERENCE TO RELATED APPLICATIONS

This U.S. non-provisional patent application claims priority under 35 U.S.C. §119 of Korean Patent Application No. 10-2014-00005438, filed on Jan. 16, 2014, the entire contents of which are hereby incorporated by reference.

### BACKGROUND OF THE INVENTION

The present invention disclosed herein relates to a light-emitting diode and a manufacturing method thereof, and more particularly, to an organic light-emitting diode and a manufacturing method thereof.

An organic light-emitting diode (OLED) is a self-emitting device that electrically excites an organic light-emitting material and emits a light. The OLED is typically referred to as an organic light-emitting device. The OLED includes a substrate, an anode, a cathode, and an organic emission layer that is formed between the anode and the cathode. Holes and electrons supplied from the anode and the cathode are bonded in the organic emission layer and generate a light that is externally emitted.

The OLED is a device in which several elements such as a substrate, an organic layer, and a metal thin film are physically stacked. A light generated from an organic emission layer proceeds upwardly or downwardly from the center of a device. Since an organic light-emitting device has a structure in which thin films having different refractive indexes are stacked, reflection appears on the interface between materials. Also, when components forming a device include a material having high reflectivity such as a metal, a resonance effect may arise in the device. Thus, interference between lights may arise. That is, when a current is applied to the organic light-emitting device to emit a light, micro resonance may necessarily involve interference. Since the micro resonance interference may involve spectrum distortion externally and an increase in spectrum viewing-angle dependency of a device, it works as the cause of a color fault of the device. In order to preserve a color, a way of inhibiting resonance and reflection in the device should be considered.

### SUMMARY OF THE INVENTION

The present invention provides an organic light-emitting diode (OLED) capable of preventing micro resonance interference, and a manufacturing method thereof.

The present invention also provides an OLED capable of enhancing productivity, and a manufacturing method thereof.

Embodiments of the inventive concept provide an organic light-emitting diode (OLED) including: a substrate; a wide viewing-angle homogenization layer on the substrate; a first electrode layer on the wide viewing-angle homogenization layer; a hole transport layer on the first electrode layer; an organic emission layer disposed on the hole transport layer to emit a light; an electron transport layer on the organic emission layer; and a second electrode layer on the electron transport layer, wherein the wide viewing-angle homogenization layer includes wave-shaped wrinkles.

In some embodiments, the wrinkles may change a travel path of a reflective light reflected from the substrate by reflection of the emitting light, differently from a travel path of the emitting light proceeding from the organic emission layer to the second electrode, and prevent micro resonance interference between the reflective light and the emitting light.

In still other embodiments, the surface wrinkles may include: crests; and troughs between the crests, wherein the crests may have a pitch of about 100 nm to 3000 nm and the troughs may have a depth of about 200 nm to 5000 nm.

In yet other embodiments, the first electrode layer to the second electrode layer may have wrinkle forms according to the surface wrinkles.

In other embodiments of the inventive concept, methods of manufacturing an organic light-emitting diode (OLED) include forming a wide viewing-angle homogenization layer on a substrate; forming a first electrode layer on the wide viewing-angle homogenization layer; forming a hole transport layer on the first electrode layer; forming an organic emission layer on the hole transport layer; forming an electron transport layer on the organic emission layer; and forming a second electrode layer on the electron transport layer, wherein the wide viewing-angle homogenization layer are formed with wave-shaped wrinkles.

In other embodiments, the forming of the wide viewing-angle homogenization layer may include: forming organic solution on the substrate; and curing the organic solution to form the wide viewing-angle homogenization layer.

In still other embodiments, the wrinkles may be formed while curing the organic solution.

In even other embodiments, the curing of the organic solution may include an ultraviolet polymerization process.

In yet other embodiments, the curing of the organic solution may include a thermal treatment process on the organic solution.

### BRIEF DESCRIPTION OF THE DRAWINGS

The accompanying drawings are included to provide a further understanding of the present invention, and are incorporated in and constitute a part of this specification. The drawings illustrate exemplary embodiments of the inventive concept and, together with the description, serve to explain principles of the present invention. In the drawings:

FIG. 1 is a cross-sectional view representing an organic light-emitting diode (OLED) according to an embodiment of the inventive concept;

FIG. 2 is a plane view of a wide viewing-angle homogenization layer;

FIG. 3 is a partial perspective view of FIG. 2;

FIG. 4 is a cross-sectional view of FIG. 3;

FIG. 5 is a graph representing spectrum according to a wide viewing-angle of a typical OLED;

FIG. 6 is a graph representing spectrum according to a wide viewing-angle of an OLED according to an embodiment of the inventive concept; and

FIGS. 7 to 13 are cross-sectional views sequentially representing a method of manufacturing an OLED according to an embodiment of the inventive concept based on FIG. 1.

### DETAILED DESCRIPTION OF PREFERRED EMBODIMENTS

Exemplary embodiments of the inventive concept are described below in detail with reference to the accompanying drawings. The advantages and features of the present invention, and implementation methods thereof will be clarified through following embodiments described with reference to the accompanying drawings. However, the present invention is not limited to embodiments to be described below but may be implemented in other forms. Rather, these embodiments are provided so that this disclosure will be thorough and complete, and will fully convey the scope of the present invention to those skilled in the art, and furthermore, the present invention is only defined by the scope of claims. The same reference numerals throughout the disclosure refer to the same components.

The terms used herein are only for explaining embodiments while not limiting the present invention. The terms of a singular form may include plural forms unless referred to the contrary. The terms used herein “includes”, “comprises”, “including” and/or “comprising” do not exclude the presence or addition of one or more components, steps, operations and/or elements other than the components, steps, operations and/or elements that are mentioned. Furthermore, since the following description presents an exemplary embodiment, the reference numerals presented according to the order of the description is not limited thereto.

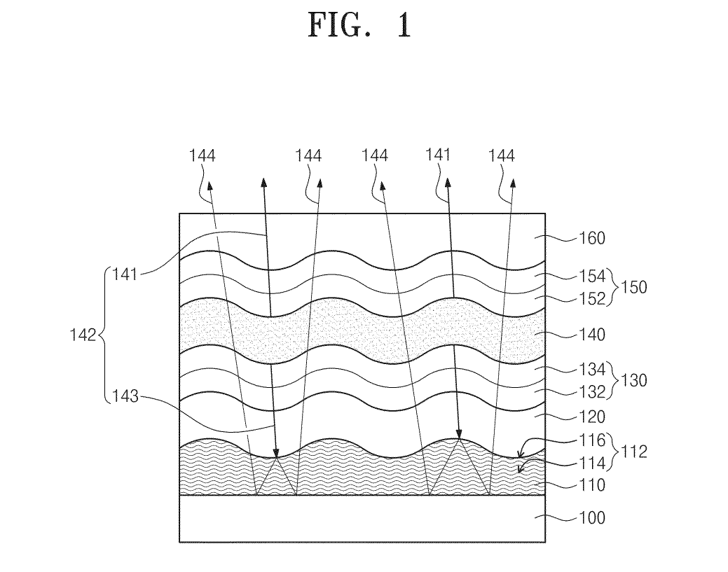

FIG. 1 shows an organic light-emitting diode (OLED) according to an embodiment of the inventive concept.

Referring to FIG. 1, an OLED according to an embodiment of the inventive concept may include a substrate 100, a wide viewing-angle homogenization layer 110, an anode layer 120, a hole transport layer 130, an organic emission layer 140, an electron transport layer 150, and a cathode layer 160.

The substrate 100 may include a glass substrate, an opaque substrate (metal foil, Si wafer, etc.), and a plastic substrate. Also, substrate 100 may include metal foil such as stainless steel foil, aluminum foil, and copper foil. The present invention is not limited thereto.

The wide viewing-angle homogenization layer 110 may be disposed on the substrate 100. The wide viewing-angle homogenization layer 110 may include a prepolymer having a photoinitiator. The wide viewing-angle homogenization layer 110 may have wrinkles 112. The wrinkles 112 may include bulk wrinkles 114 and surface wrinkles 116. The bulk wrinkles 114 may be disposed in the wide viewing-angle homogenization layer 110. The surface wrinkles 116 may be disposed on the upper surface of the wide viewing-angle homogenization layer 110. The surface wrinkles 116 may be formed as wrinkles having a larger wave form than the bulk wrinkles 114.

The anode layer 120 may be disposed on the wide viewing-angle homogenization layer 110. The anode layer 120 may wrinkle according to the wrinkles 112 of the wide viewing-angle homogenization layer 110. The anode layer 120 may be a conductive material. For example, the anode layer 120 may be one of transparent conductive oxides (TCO). As an example, the anode layer 120 may be one of an indium tin oxide (ITO) or an indium zinc oxide (IZO). Also, a metal material such as silver (Ag), aluminum (Al), magnesium (Mg) or calcium (Ca) may also be selected. Also, a carbon based material such as graphene or carbon nano tube may also be selected.

The hole transport layer 130 may be disposed on the anode layer 120. The hole transport layer 130 may include a hole diffusion layer 132 and a hole injection layer 134. The hole injection layer 134 may be disposed on the hole diffusion layer 132. The hole transport layer 130 may include an organic compound or a metallic complex compound.

The organic emission layer 140 may be disposed on the hole transport layer 130. The organic emission layer 140 may include an organic compound or a metallic complex compound. The organic emission layer 140 may include a combination of an organic material that is host, and dopant for color reproduction. The organic emission layer 140 may generate an emitting light 142. The emitting light 142 may be a white light. The present embodiment is not limited thereto. The emitting light 142 may also have various colors.

The emitting light 142 may include an upward emitting light 141 and a downward emitting light 143. The upward emitting light may proceed from the organic emission layer 140 toward the cathode layer 160 on the organic emission layer 140. The downward emitting light 143 may proceed from the organic emission layer 140 toward the substrate 100. The proceeding direction of the downward emitting layer 143 may randomly vary by the wrinkles 112 of the wide viewing-angle homogenization layer 110. The downward emitting light 143 may proceed toward the direction of the wide viewing-angle homogenization layer 110 in which a refractive index is high. The refractive indexes of the wrinkles 112 may variously vary. Nevertheless, most of the downward emitting lights 143 may be incident on the substrate 100. The downward emitting light 143 may be reflected from the substrate 100.

The hole transport layer 150 may be disposed on the organic emission layer 140. The hole transport layer 150 may include an electron injection layer 152 and an electron diffusion layer 154. The electron diffusion layer 154 may be provided to the electron injection layer 152. The electron transport layer 150 may include an organic compound or a metallic complex compound.

The cathode layer 160 may be disposed on the electron transport layer 150. The cathode layer 160 may be selected as a conductive material. A metal thin film material for a cathode may include silver (Ag), aluminum (Al), magnesium (Mg) or calcium (Ca). A corresponding material may be selected from a thin metal oxide, a conductive transparent oxide, and a carbon based material. Since a top & bottom or top emission device needs transparency, a thin film including silver (Ag) as an example of a thin metal may be selected and the thickness may be within a range of approximately 5 nm to 300 nm. The carbon based material may include graphene or carbon nano tube.

A reflective light 144 may proceed from the substrate 100 toward the cathode layer 160. The reflective light 144 may proceed in a direction different from the downward emitting light 143 and the upward emitting light 141. The reason for this is because the reflective light 144 is refracted at the wrinkled electrode surface of the wide viewing-angle homogenization layer 110.

For a typical OLED, the travel directions of the reflective light 144 and the emitting light 142 may be parallel to each other. The reflective light 144 and the emitting light 142 that are white may involve spectrum distortion due to micro resonance interference. Some wavelength spectrum may be reinforced and other wavelength spectrum may be cancelled. Also, when a viewing angle q is not perpendicular (q=0°) to the substrate 100, the length of an optical path varies and thus specific wavelength spectrum dependency of the reflective light 144 and the emitting light 142 according to an angle may appear.

That is, spectrum may differently appear according to a viewing angle.

The wide viewing-angle homogenization layer 110 may prevent micro resonance interference between the reflective light 144 and the emitting light 142. The wrinkles 112 may allow the reflective light 144 to proceed in a random direction. The reflective light 144 may proceed from the wrinkles 112 at a radiation angle, from a direction perpendicular to the substrate 100 to a direction parallel thereto. The reflective light 144 may proceed on a region within the radiation angle with averagely the same amount. Thus, the wide viewing-angle homogenization layer 110 may remove the viewing-angle dependency of the reflective light 144 and the emitting light 142.

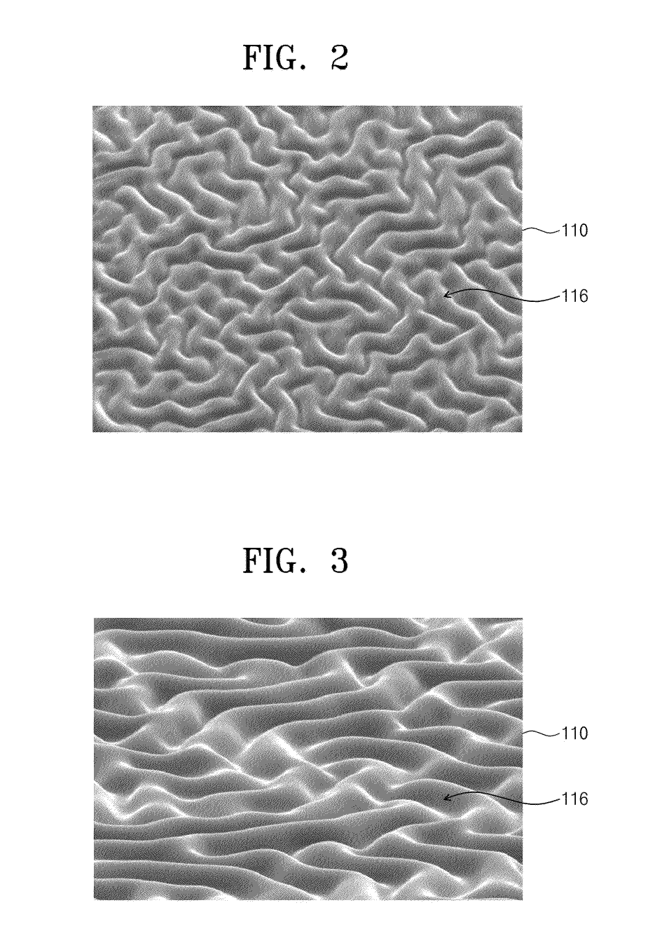

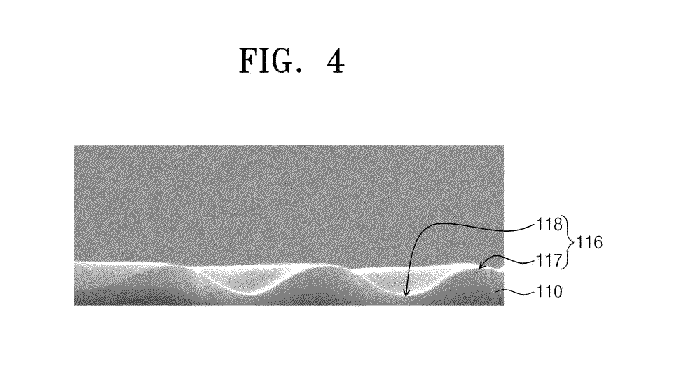

FIG. 2 is a plane view of the wide viewing-angle homogenization layer 110. FIG. 3 is a partial perspective view of FIG. 2. FIG. 4 is a cross-sectional view of FIG. 3.

Referring to FIGS. 1 to 4, the surface wrinkles 116 may be irregularly formed on the upper surface of the wide viewing-angle homogenization layer 110. The surface wrinkles 116 may have a wave form. That is, the surface wrinkles 116 may be wave form wrinkles. The surface wrinkles 116 may have crests 117 and troughs 118. For example, the crests 117 may have a pitch of about 100 nm to 3000 nm. The troughs 118 may have a depth of about 200 nm to 5000 nm.

The anode layer 120 to the cathode layer 160 may have a wavy shape according to the wave form of the surface wrinkles 116. The surface wrinkles 116 and the wavy shape may remove the viewing-angle dependency of the reflective light 144 and the emitting light 142.

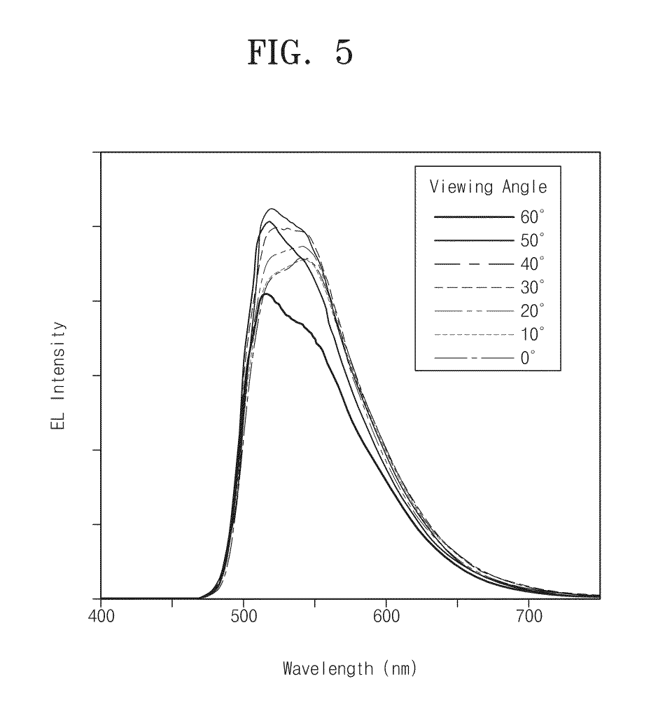

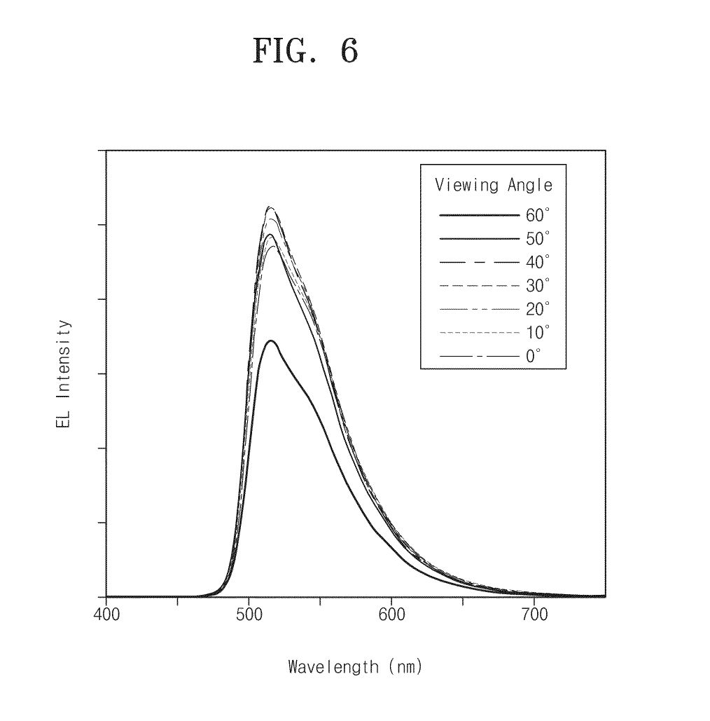

FIG. 5 is a graph representing spectrum according to a wide viewing-angle of a typical OLED. FIG. 6 is a graph representing spectrum according to a wide viewing-angle of an OLED according to an embodiment of the inventive concept.

Referring to FIGS. 5 and 6, since in the case of the typical OLED, a spectrum shape and a central wavelength do not match, spectrum distortion according to a change in viewing angle may arise. However, the OLED according to an embodiment of the inventive concept may have a spectrum shape and a central wavelength that almost match, even though a viewing angle varies. Thus, it is possible to prevent spectrum distortion according to a viewing angle. In this example, the horizontal axis represents the length of a spectrum wavelength and the vertical axis represents the intensity of spectrum.

A method of manufacturing the OLED according to the embodiment of the inventive concept having such a configuration is as follows.

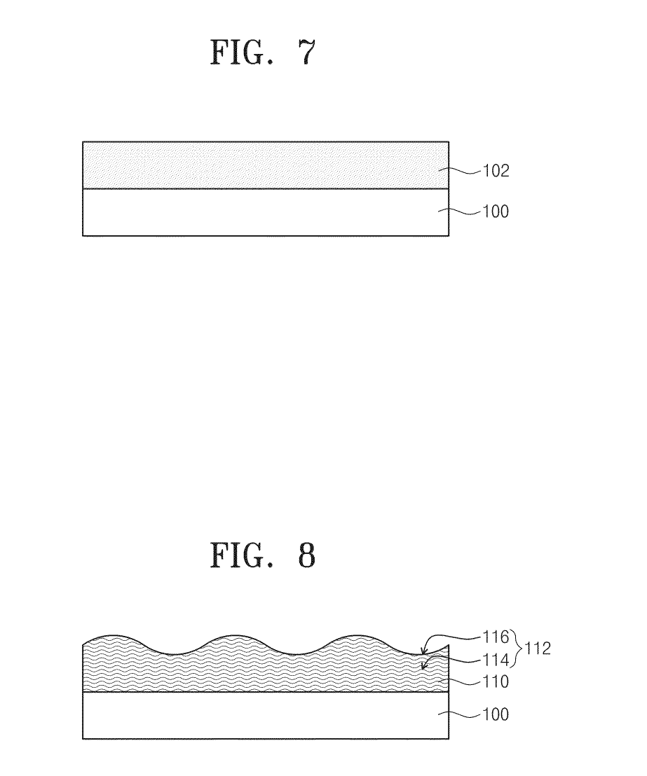

FIGS. 7 to 13 are cross-sectional views sequentially representing a method of manufacturing an OLED according to an embodiment of the inventive concept based on FIG. 1.

Referring to FIG. 7, organic solution 102 is applied onto the substrate 100. The organic solution 102 may include prepolymer liquid and a photoinitiator in the prepolymer liquid. The applying of the organic solution 102 may be performed in a vapor organic solvent atmosphere. The applying of the organic solution 102 may include printing or spin coating.

Referring to FIG. 8, the organic solution 102 is cured to form the wide viewing-angle homogenization layer 110. The wrinkles 112 of the wide viewing-angle homogenization layer 110 may be easily formed when curing the organic solution 102. The wrinkles 112 may be formed by prepolymer cross linkage and perturbation. The wrinkles 112 may include the bulk wrinkles 114 and the surface wrinkles 116. The surface wrinkles 116 may have a wave form. The curing of the organic solution 102 may include an ultraviolet polymerization process. The ultraviolet polymerization process may be performed in an inert gas atmosphere. The inert gas may include nitrogen and argon.

The ultraviolet polymerization process is a production process cheaper than a typical photolithography process and a typical etching process. The present invention is not limited thereto and various variations may be implemented. For example, the curing of the organic solution 102 may further include a thermal treatment process cheaper than a photolithography process.

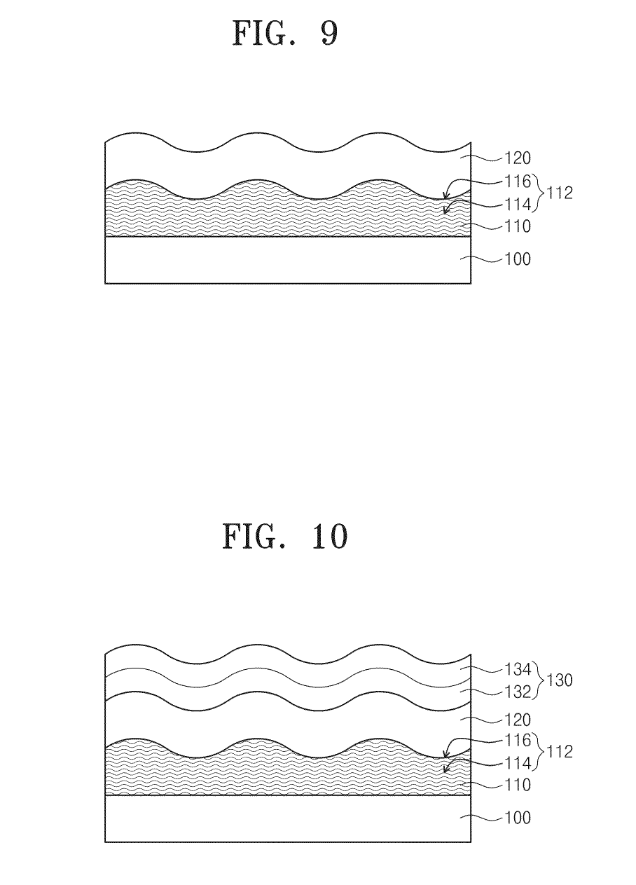

Referring to FIG. 9, the anode layer 120 is formed on the wide viewing-angle homogenization layer 110. The anode layer 120 may be formed in a wavy shape according to the surface wrinkles 116.

Referring to FIG. 10, the hole transport layer 130 is formed on the anode layer 120. Likewise, the hole transport layer 130 may be formed in a wavy shape. The anode layer 120 and the hole transport layer 130 may include a metal. The hole transport layer 130 may include the hole diffusion layer 132 and the hole injection layer 134. The hole injection layer 134 may be formed on the hole diffusion layer 132.

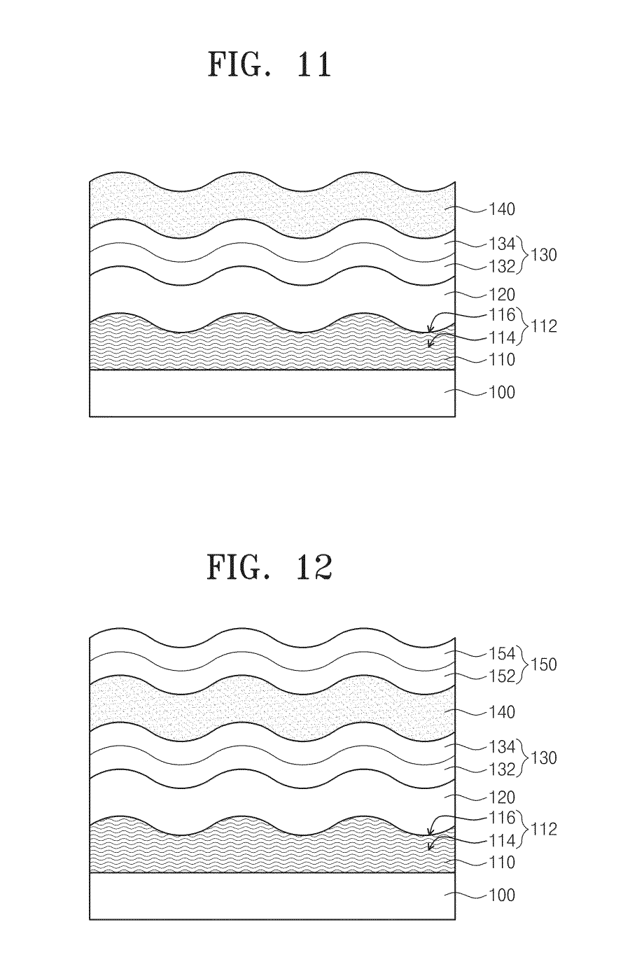

Referring to FIG. 11, the hole transport layer 130 is formed on the organic emission layer 140. The organic emission layer 140 may include an organic compound that is formed by printing or dropping. The organic emission layer 140 may be formed in a wavy shape.

Referring to FIG. 12, the electron transport layer 150 is formed on the organic emission layer 140. The electron transport layer 150 may be formed in a wavy shape. The electron transport layer 150 may include the electron injection layer 152 and the electron diffusion layer 154. The electron diffusion layer 154 may be formed on the electron injection layer 152.

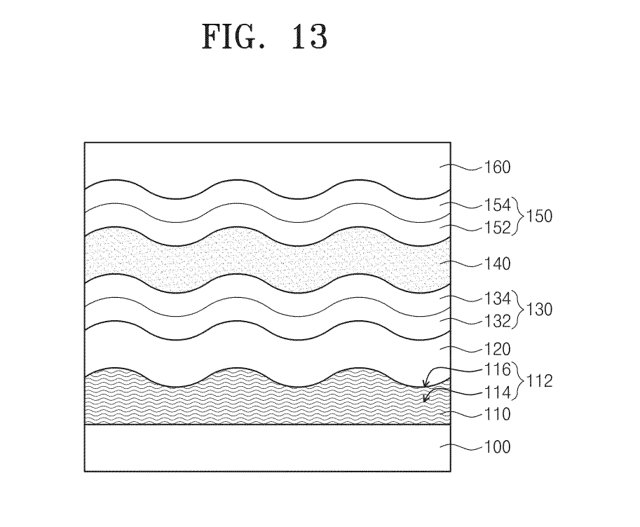

Referring to FIG. 13, the cathode layer 160 is formed on the electron transport layer 150. The anode layer 160 may be formed in a wavy shape.

As described above, the OLED according to embodiments of the inventive concept may include the wide viewing-angle homogenization layer that is disposed between the substrate and the organic emission layer and has the wrinkles. The wrinkles may change the travel path of the reflective light from the substrate differently from the travel path of the emitting light from the organic emission layer. The wrinkles may prevent micro resonance interference between the reflective light and the emission light. Also, the wrinkles may be easily formed when curing the organic solution on the substrate. The organic solution may be cured by the ultraviolet polymerization process.

The ultraviolet polymerization process is a production process cheaper than a typical photolithography process and a typical etching process.

While embodiments of the inventive concept are described with reference to the accompanying drawings, a person skilled in the art will be able to understand that the present invention may be practiced in other particular forms without changing technical spirits or essential characteristics. Therefore, embodiments described above should be understood as illustrative and not limitative in every aspect.

What is claimed is:

1. An organic light-emitting diode (OLED) comprising:
a substrate;
a wide viewing-angle homogenization layer on the substrate;
a first electrode layer on the wide viewing-angle homogenization layer;
a hole transport layer on the first electrode layer;
an organic emission layer disposed on the hole transport layer to emit a light;
an electron transport layer on the organic emission layer; and
a second electrode layer on the electron transport layer,
wherein the wide viewing-angle homogenization layer comprises wave-shaped wrinkles reflecting a light to the organic emission layer.

2. The organic light-emitting diode (OLED) of claim 1, wherein the wrinkles changes a travel path of a reflective light reflected from the substrate by reflection of the emitting light, differently from a travel path of the emitting light proceeding from the organic emission layer to the second electrode, and prevents micro resonance interference between the reflective light and the emitting light.

3. The organic light-emitting diode (OLED) of claim 1, wherein the wrinkles comprise:
crests; and
troughs between the crests,
wherein the crests have a pitch of about 100 nm to 3000 nm. And the troughs have a depth of about 200 nm to 5000 nm.

4. The organic light-emitting diode (OLED) of claim 3, wherein the first electrode layer to the second electrode layer have wrinkle forms according to the wrinkles.

5. A method of manufacturing an organic light-emitting diode (OLED), the method comprising:
forming a wide viewing-angle homogenization layer on a substrate;
forming a first electrode layer on the wide viewing-angle homogenization layer;
forming a hole transport layer on the first electrode layer;
forming an organic emission layer on the hole transport layer;
forming an electron transport layer on the organic emission layer; and
forming a second electrode layer on the electron transport layer,
wherein the wide viewing-angle homogenization layer are formed with wave-shaped wrinkles.

6. The method of claim 5, wherein the forming of the wide viewing-angle homogenization layer comprises:
forming organic solution on the substrate; and
curing the organic solution to form the wide viewing-angle homogenization layer.

7. The method of claim 6, wherein the wrinkles are formed while curing the organic solution.

8. The method of claim 6, wherein the curing of the organic solution comprises an ultraviolet polymerization process.

9. The method of claim 6, wherein the curing of the organic solution comprises a thermal treatment process on the organic solution.
